(19) United States
(12) Patent Application Publication
(10) Pub. No.: US 2014/0146302 A1
(43) Pub. Date: May 29, 2014

(54) DEVICE FOR HOMOTHETIC PROJECTION OF A PATTERN ONTO THE SURFACE OF A SAMPLE, AND LITHOGRAPHY METHOD USING SUCH A DEVICE

(71) Applicant: Jérôme Polesel, Gif-sur-yvette (FR)

(72) Inventor: Jérôme Polesel, Gif-sur-yvette (FR)

(21) Appl. No.: 13/881,842

(22) PCT Filed: Oct. 25, 2011
(86) PCT No.: PCT/EP11/68587

§ 371 Date: May 10, 2013

(30) Foreign Application Priority Data
Oct. 29, 2010 (FR) 1058972

(51) Int. Cl. G03F 7/20; G02B 21/06

(52) U.S. Cl. CPC G03F 7/7055; G02B 21/06
USPC 355/77; 359/385

(57) ABSTRACT

The invention relates to a device for homothetic projection of a pattern onto the surface of a sample (21) comprising a photosensitive zone. The device comprises means allowing a pattern to be projected onto the surface of the sample, and an optical system (12) allowing the size of the pattern projected onto the surface of the sample to be continuously controlled. The invention also relates to a photolithography method using such a projection device, and to a method and a kit for converting an optical microscope into such a projection device.

### TECHNICAL FIELD

The present invention relates to a device for homothetic projection of a pattern onto the surface of a sample that comprises a photosensitive zone by using radiation to which the photosensitive zone is sensitive. The present invention also relates to a photolithography device. The present invention allows the size of the pattern projected onto the surface of the sample to be continuously changed by using the same photolithography mask. The present invention also relates to a photolithography method using such a device, and to a method and a kit for converting an optical microscope into such a pattern projection device.

### PRIOR ART

Photolithography is a technique commonly used in microelectronics for structuring layers of materials according to chosen patterns. To do this, a photosensitive layer is deposited onto a substrate. This photosensitive layer is then illuminated through a mask with a light to which the photosensitive layer is sensitive. The light generally allows crosslinking or polymerization of the photosensitive layer, particularly when the wavelength of the light used is ultraviolet. The photosensitive layer is then chemically developed so as to only leave exposed zones on the substrate if the photosensitive layer is a negative photoresist, or on the contrary only non-exposed zones, if the photosensitive layer is a positive photoresist. The photosensitive layer remaining on the substrate may then itself be used as a mask to define a localized action in the substrate that it covers: the action of etching of an underlying layer at the points where the photoresist is absent, the action of implanting impurities at the points where the photoresist is absent, etc.

Just recently, photolithography is no longer only used in the microelectronics field, but also in fields such as biochemistry or biotechnologies, particularly to manufacture biochips.

However, current photolithography techniques are relatively costly since existing photolithography devices are expensive. In addition, existing photolithography devices use expensive masks. Therefore, current photolithography techniques are difficult to access for biotechnology or biochemistry laboratories, especially when they only occasionally use photolithography.

In addition, with current photolithography devices, when one wishes to change the size of the pattern made on the surface of the substrate, changing the mask is necessary, which complicates the photolithography method and increases the cost.

### DISCLOSURE OF THE INVENTION

The invention aims to remedy the disadvantages from the prior art by proposing a device for projecting a pattern onto the surface of a sample that comprises at least one photosensitive zone, the device allowing the size of the pattern projected onto the surface of the sample to be continuously changed, without having to change the mask.

Another object of the invention is to propose a device for projecting a pattern onto the surface of a sample that is inexpensive.

Another object of the invention is to propose a device for projecting a pattern onto the surface of a sample that allows an inexpensive mask to be used.

To do this, a device for projecting a pattern onto the surface of a sample that comprises at least one photosensitive zone is proposed according to a first aspect of the invention, the projection device comprising:
a mask defining a base pattern,
at least one photoactivating light source able to illuminate the sample through the mask with radiation to which the photosensitive zone is sensitive so as to define a projected pattern on the sample;
an optical system disposed between the mask and the sample, the optical system being able to carry out controlled homothety between the size of the base pattern and the size of the projected pattern.

In this document, the image of the base pattern that is formed on the sample, and more precisely on the surface of the sample, thanks to a light source that sends radiation to the sample through the mask, is called the “projected pattern.” Preferably, the projected pattern does not have the same size as the base pattern. The size of the projected pattern may vary, without the size of the base pattern varying. In fact, the optical system continuously varies the size of the projected pattern.

The projection device thus projects onto the sample, and more precisely onto the photosensitive zone of the sample, the image of the base pattern by reducing or enlarging it, such that projected patterns of different sizes may be projected onto the surface of the sample with the same mask.

The device according to the invention may also present the following characteristics, considered individually or according to all technically possible combinations.

According to an embodiment, the device comprises a sample holder capable of holding the sample.

According to an embodiment, the device comprises a mask holder to hold the mask.

According to different embodiments, the photoactivating light source may be an infrared source, a UV ultraviolet source or a VUV (Vacuum Ultraviolet) source.

The photoactivating light source is preferably collimated.

According to an embodiment, the mask presents transparent zones and opaque zones, the transparent zones allowing the radiation issued from the photoactivating light source to pass, the opaque zones selectively blocking the transmission of the radiation issued from the photoactivating light source.

Therefore, depending on different embodiments:
the base pattern may be an opaque pattern, for example deposited by printing or spraying, or existing in the structure of the mask;
the base pattern may be a transparent or empty pattern, the rest of the mask being opaque,
the base pattern may be formed by the shape of the mask, that is then opaque, the shape of the mask may be projected entirely onto the sample.

According to an embodiment, the projection device comprises:
an objective presenting an image focal plane and an object focal plane, the sample being disposed in the image focal plane of the objective;
a primary diaphragm disposed in the object focal plane of the objective, the photoactivating light source being able to illuminate the plane in which the primary diaphragm is found so as to define an intermediate pattern in the plane of the primary diaphragm,
the optical system presenting an object focal plane in which the mask is situated and an image focal plane in which the primary diaphragm is situated, the optical system being able to carry out controlled homothety between the size of the base pattern on the mask and the size of the intermediate pattern.

The plane of the primary diaphragm is preferably merged with the object focal plane of the objective.

In this document, the image of the base pattern in the plane of the primary diaphragm is called the “intermediate pattern.” The intermediate pattern is therefore the image of the base pattern formed by the optical system in the plane of the primary diaphragm.

Therefore, the image of the base pattern is formed in the plane of the primary diaphragm, so as to form the intermediate pattern. The optical system allows a first homothety with a controllable ratio to be carried out between the size of the intermediate pattern and the size of the base pattern. Next, the image of the intermediate pattern is formed by the objective on the sample to form the projected pattern. The objective therefore allows a second homothety to be carried out with a fixed ratio previously defined between the size of the intermediate pattern and the size of the projected pattern. Therefore, thanks to these two successive homotheties, the size of the projected pattern may be very different from the size of the base pattern.

According to an embodiment, the sample presents a sample surface that is not parallel to the image focal plane of the objective.

According to an embodiment, the sample surface is not planar.

In these two cases, the optical system preferably comprises means for adjusting the definition of the pattern projected onto the surface of the sample.

According to an embodiment, the optical system comprises reduction means able to control the size of the intermediate pattern. These reduction means allow a first control of the size of the intermediate pattern and therefore of the projected pattern.

According to an embodiment, the optical system comprises three types of means:
Means for controlling the size of the intermediate pattern;
Means for controlling the definition of the intermediate pattern;
Means for controlling the luminous intensity of the projected pattern that simultaneously modifies the brightness and contrast of the intermediate pattern. Brightness may be defined as being the total quantity of light energy radiated, i.e., the number of photons per unit area of the intermediate pattern. Contrast may be defined as being the light distribution between dark and light parts of the intermediate pattern.

Depending on different embodiments:
the optical system presents an optical axis that is merged with the optical axis defined by the light source and the mask, and the reduction means comprise an afocal system comprising two negative lenses separated by a positive lens, the negative lenses and the positive lens may be displaced along the optical axis of the optical system so as to control the size of the intermediate pattern; this embodiment allows a very high quality projected pattern to be obtained since it prevents optical aberrations, or
the optical system presents an optical axis and the reduction means comprise a negative lens able to be displaced along the optical axis of the optical system so as to control the size of the intermediate pattern. This embodiment is simpler than the previous. However, when the base pattern has a too-large lateral size, the projected pattern may be deformed due to optical aberrations. In order to reduce these optical aberrations, the lens may be polished so as to be parabolic so as to reduce the optical aberrations. Optical simulation calculations may be carried out beforehand to prevent these aberrations by defining the most suitable size of the base pattern.

According to an embodiment, the optical system also comprises focusing means able to adjust the definition of the intermediate pattern. These focusing means compensate for the effects of the reduction means that modify the focal distance of the optical system. These focusing means thus allow that the light rays emitted by the photoactivating light source always converge in the plane of the primary diaphragm, such that the image of the base pattern is always sharp in the plane of the primary diaphragm.

According to an embodiment, the optical system also comprises an additional diaphragm able to adjust the brightness and contrast of the intermediate pattern that is formed in the plane of the primary diaphragm. Thus, the additional diaphragm adjusts the brightness and contrast of the intermediate pattern and thus of the projected pattern.

According to an embodiment, the projection device also comprises a visualizing light source, that is preferably collimated, able to emit visible radiation that illuminates the sample through the mask.

Depending on different embodiments:
The photoactivating light source and the visualizing light source may be one and the same light source, a filter enabling passage from the visualization mode where one visualizes the projected pattern on the surface of the sample without modifying it, to the photoactivation mode where the surface of the sample is irradiated, and conversely.
The photoactivating light source and the visualizing light source are two light sources that are distinct from each other.

The visible radiation from the visualizing light source generally follows the same optical path as the radiation emitted by the photoactivating light source to traverse the part of the projection device between the mask and the sample. This visualizing light source emits visible radiation to which the photosensitive zone is not sensitive or is not very sensitive, which projects the pattern projected onto the surface of the sample without modifying the photosensitive zone. Therefore, the projection device presents two operational modes:
according to the first operational mode, called the “visualization mode,” the sample is illuminated through the mask thanks to the visualizing light source such that the projected pattern is visible on the surface of the sample. Therefore, a user may visualize the pattern projected onto the surface of the sample, without the photosensitive zone necessarily being modified. This first operational mode particularly performs adjustments relating to the size, definition, brightness and contrast of the pattern projected by using the optical system without modifying the photosensitive zone.
according to the second operational mode, called the “writing mode,” the sample is illuminated through the mask thanks to the photoactivating light source such that the projected pattern defines a photosensitized zone in the photosensitive zone. Therefore, the parts of the photosensitive zone that have been exposed to radiation from the photoactivating source were modified with relation to the parts of the photosensitive zone that were not exposed to radiation.

According to an embodiment, the projection device also comprises a filter able to filter and absorb the radiation emitted by the visualizing light source and to which the photosensitive zone is sensitive. Therefore, the filter only allows radiation to which the photosensitive zone is not sensitive to pass through, such that the photosensitive zone may be exposed at length to the radiation from the visualizing light source without being modified.

According to an embodiment, the projection device also comprises selection means able to select either the photoactivating light source or the visualizing light source to illuminate the sample through the mask.

Therefore the selection means allow passage from the visualization mode to the writing mode and vice-versa.

When the photoactivating light source and the visualizing light source are one and the same light source, the selection means preferably comprise a filter able to filter and absorb the radiation from the light source to which the photosensitive zone is sensitive, while allowing radiation enabling visualization of the pattern projected onto the surface of the sample to pass through without modifying the photosensitive zone. The filter may either be placed before the light source or not according to whether one is in reading mode or writing mode.

When the photoactivating light source and the visualizing light source are two distinct light sources, the selection means preferably comprise means enabling the radiation from the visualizing light source and the radiation from the photoactivating light source to be alternatively directed, particularly through the mask and the optical system so as to project the base pattern onto the surface of the sample.

According to an embodiment, the device also comprises a system of controlled displacement enabling the sample to be laterally and axially displaced.

According to an embodiment, the device also comprises a system for the controlled switching on and switching off of the photoactivating light source.

A second aspect of the invention relates to a photolithography method using a projection device according to a first aspect of the invention, the method comprising the following steps:
(a) a step of adjusting the size of the pattern projected onto the surface of the sample by using radiation (22) emitted by the visualizing light source (7);
(b) a step of projecting the pattern projected onto the sample with the radiation emitted by the photoactivating light source;
(c) a step of eliminating the parts of the photosensitive zone that have been exposed to radiation or else a step of eliminating the parts of the photosensitive zone that were not exposed to radiation.

Therefore, during step (a), the optical system, and possibly the objective, are adjusted so as to be able to adjust the size of the desired projected pattern onto the surface of the sample. To do this, the visualizing light source is preferably used, so as to be able to visualize the surface of the sample with the projected pattern above, without modifying the photosensitive zone. Once the pattern projected onto the surface of the sample has been adjusted, the sample is illuminated, during step (b), through the mask with the photoactivating light source so as to print the projected pattern in the photosensitive zone. This step (b) takes place for a chosen time so as to optimize exposure to radiation from the photosensitive zone. Lastly, the projected pattern is revealed in the photosensitive zone by eliminating either the parts of the photosensitive zone that were not exposed to radiation in the case of a positive photoresist, or the parts of the photosensitive zone that were exposed to radiation in the case of a negative photoresist.

According to an embodiment, the size of the projected pattern is reduced with relation to the size of the base pattern, which allows defects in the base pattern to be eliminated by reducing these defects below the diffraction limit.

Another aspect of the invention also relates to a method of photoactivating chemical or biological species using a projection device according to the first aspect of the invention, the method comprising the following steps:
(a) a step of adjusting the size of the pattern projected onto the surface of the sample by using radiation (22) emitted by the visualizing light source (7);
(b) a step of projecting the pattern projected onto the sample with the radiation emitted by the photoactivating light source to locally activate chemical or biological species that are photosensitive.

According to an embodiment, the mask used in the photolithography method or in the photoactivation method is formed of a transparent sheet on which the base pattern is printed. Even if the act of printing the base pattern by using a conventional printer generates defects on the base pattern, it turns out that the projected pattern, of a size smaller than that of the base pattern, will be a good-quality pattern since the defects likely to be present on the projected pattern have a reduced size with relation to those from the base pattern. In fact, homothety enables the defects from the base pattern to be reduced in size below the diffraction limit. Thus, the projection device according to the invention and the method according to the invention are particularly advantageous since they enable inexpensive masks to be used, without the quality of the pattern projected onto the sample being adversely affected.

A third aspect of the invention also relates to a method to convert an optical microscope into a device for projecting a pattern onto the surface of a sample comprising at least one photosensitive zone, the optical microscope comprising:
an objective defining an object focal plane and an image focal plane;
a primary diaphragm disposed in the object focal plane of the objective, the primary diaphragm extending in a plane;
the sample being disposed in the image focal plane of the objective;
   the conversion method comprising, in any order, the following steps:
at least one photoactivating light source emitting radiation to which the photosensitive zone is sensitive so as to define a projected pattern on the sample is added to the optical microscope;
a mask disposed between the photoactivating light source and the sample is added to the optical microscope, the mask defining a base pattern;
an optical system disposed between the mask and the sample, the optical system being able to carry out controlled homothety between the size of the base pattern and the size of the projected pattern is added to the optical microscope.

The plane of the primary diaphragm and the object focal plane of the objective are preferably merged.

Advantageously, the microscope also comprises a sample holder able to hold the sample.

Depending on different embodiments:
the sample holder of the microscope is initially able to displace the sample in a controlled manner; or
the method comprises a step of adding to the sample holder a system for the lateral and axial displacement of the sample holder.

The conversion method is particularly advantageous since it modifies an optical microscope, that is generally a reflection microscope, into a projection device and particularly into a photolithography device. Thus, from a conventional optical microscope, which is inexpensive and found in most biotechnology or biochemistry laboratories, a photolithography device may be obtained by adding just a few elements. This conversion method thus enables laboratories that only use photolithography occasionally, or that have few means, to be provided with a low-cost photolithography device. In addition, as explained previously, this photolithography device projects onto the sample a projected pattern of reduced size with relation to the base pattern on the mask and consequently, this photolithography device enables the use of masks made from a simple transparent sheet on which the desired base pattern has been printed. In addition, a controlled lateral displacement of the sample and controlled switching on/switching off of the photoactivating light source enables the pattern projected onto the sample to be replicated in the form of a continuous matrix or line.

According to an embodiment, the image focal plane of the optical system is placed in the plane of the primary diaphragm.

According to an embodiment, the mask is placed in the object focal plane of the optical system.

According to an embodiment, the optical microscope comprises a visualizing light source, the method also comprising a step of adding, in the optical microscope, selection means able to select either the photoactivating light source or the visualizing light source to illuminate the sample through the mask. These selection means may for example be constituted of a mirror that may pivot between two positions:
in the first position, the mirror directs the radiation from the visualizing light source such that it illuminates the sample through the mask;
in the second position, the mirror directs the radiation from the photoactivating light source such that it illuminates the sample through the mask.

According to an embodiment, the conversion method also comprises a step of adding a filter able to filter and absorb radiation emitted by the visualizing light source and to which the photosensitive zone is sensitive.

According to an embodiment, the optical system comprises:
reduction means able to control the size of the image of an object;
focusing means able to adjust the definition of the image of the object;
an additional diaphragm able to adjust the brightness and contrast of the image of the object.

According to an embodiment, the microscope comprises a system for the controlled lateral displacement of the sample holder and the photoactivating light source is equipped with a system for the controlled switching on/switching off of the photoactivating light source. These two means enable the pattern projected onto the sample to be replicated in the form of a continuous matrix or line.

A fourth aspect of the invention also relates to a kit for converting an optical microscope into a device for projecting a pattern onto the surface of a sample comprising at least one photosensitive zone, the kit comprising:
a mask holder able to hold a mask;
a photoactivating light source emitting radiation to which the photosensitive zone is sensitive; This photoactivating light source is preferably equipped with a system for the controlled switching on/switching off of the photoactivating light source;
an optical system able to perform an optical reduction or optical magnification.

The conversion kit may also comprise a system for the controlled displacement of the sample holder.

The kit is particularly advantageous since it is inexpensive and simply fits onto an optical reflection microscope.

According to an embodiment, the optical system comprises:
reduction means able to control the size of the image of an object;
focusing means able to adjust the definition of the image of the object;
an additional diaphragm able to adjust the brightness of the image of the object.

According to an embodiment, the kit also comprises selection means able to direct radiation emitted by a light source through an object.

According to an embodiment, the kit also comprises a filter able to filter and absorb the radiation to which the photosensitive zone is sensitive.

### BRIEF DESCRIPTION OF THE FIGURES

Other characteristics and advantages of the invention will emerge upon reading the following detailed description, with reference to the attached figures, that illustrate:

FIG. 1, a schematic cross sectional view of a photolithography device according to an embodiment of the invention;

FIG. 2, a schematic cross sectional view of the optical system of the device from FIG. 1;

FIG. 3, a schematic cross sectional view of the steps of a photolithography method implemented with the device from FIG. 1.

For more clarity, identical or similar elements are marked by identical reference signs on all of the figures.

### DETAILED DESCRIPTION OF AT LEAST ONE EMBODIMENT

A projection device according to an embodiment of the invention will now be described in the case where this projection device is a photolithography device.

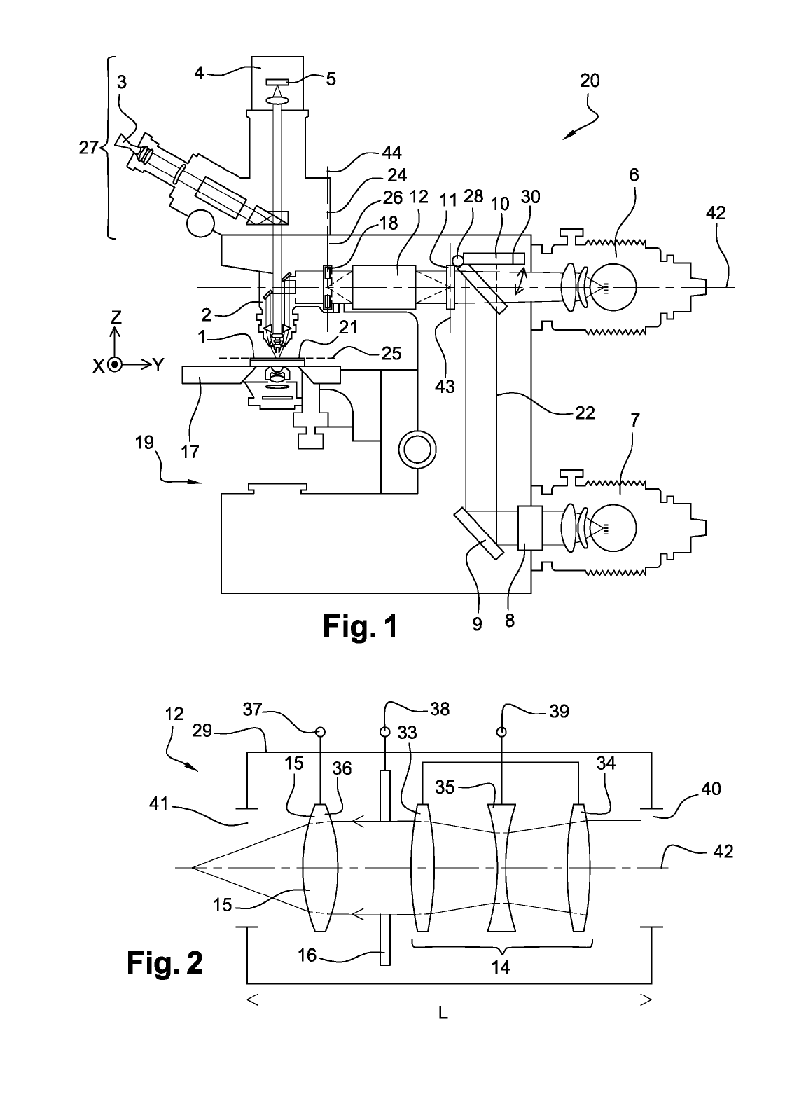

FIG. 1 thus represents a projection device 20 that is a photolithography device. This projection device comprises an optical reflection microscope 19 and a kit for converting the optical microscope 19 into a projection device.

The optical microscope comprises a sample holder 1 able to hold a sample 21. The sample 21 comprises a photosensitive zone on its surface that here is a layer of photosensitive photoresist that completely covers sample 21. In this example, the photosensitive photoresist layer is sensitive to UV or VUV rays. The photosensitive photoresist layer may be a positive photoresist or a negative photoresist layer.

The sample holder 1 is disposed on a movable table 17 that may be displaced in translation in the X and Y axes. Movable table 17 may also be displaced in translation in the Z axis.

According to different embodiments, the movable table 17 may be manually or automatically displaced, for example thanks to piezoelectric actuators or stepper motors. The act of displacing movable table 17 with piezoelectric actuators or stepper motors enables more precise displacements. Interfacing of these actuators enables the pattern projected onto the sample to be replicated in the form of a continuous matrix or line. However, this embodiment is more expensive than the manual mode.

The optical microscope also comprises a collimated broad-spectrum visualizing light source 7 that emits filtered light 22 in order to illuminate sample 21.

Optical microscope 19 also comprises a primary diaphragm 18 that limits the angular size of the light beam emitted by the visualizing light source 7. The primary diaphragm 18 extends in a plane 26.

Optical microscope 19 also comprises an objective 2 that presents an object focal plane 24 and an image focal plane 25. The upper surface of sample 21 is placed in the image focal plane 25 of objective 2. Primary diaphragm 18 is placed in the object focal plane 24 of objective 2 such that planes 26 and 24 are merged.

Optical microscope 19 also comprises means 27 for visualizing the surface of sample 21. These visualizing means may comprise an eyepiece 3 and/or sensor 5 of a CCD or CMOS camera 4.

The elements constituting the optical reflection microscope are known from the prior art and they are only given here for indicative purposes, without necessarily limiting the invention.

A method of converting the optical microscope 19 from FIG. 1 into a projection device by using a conversion kit will now be described.

The conversion kit comprises a mask holder able to hold a mask 11.

The conversion kit also comprises a collimated photoactivating light source 6 that emits radiation to which the photosensitive zone of the sample is sensitive. In this example, the photosensitive zone is sensitive to UV or VUV radiation and consequently, the photoactivating light source emits UV or VUV radiation.

The conversion kit also comprises selection means 30 able to direct radiation through an object. Here these selection means 30 comprise a mirror 10 that is movable in rotation around a hinge 28.

The conversion kit also comprises a filter 8 that filters radiation to which the photosensitive zone of the sample is sensitive. In the present case, filter 8 thus absorbs UV and/or VUV radiation.

The conversion kit also comprises an optical system 12, schematically represented in FIG. 2. This optical system preferably carries out an optical reduction of an object. Optical system 12 may also carry out an optical magnification.

As represented in FIG. 2, the optical system 12 comprises a housing 29. Housing 29 comprises two orifices 40 and 41 situated on both sides of the housing. These two orifices 40 and 41 enable light to traverse housing 29. In housing 29, optical system 12 may comprise reduction means 14, focusing means 15 and an additional diaphragm 16 that are aligned along an optical axis 42.

Reduction means 14 may for example be formed by two negative lenses 33 and 34 separated by a positive lens 35.

Focusing means 15 may comprise a negative lens 36 that focuses the light rays traversing it.

The additional diaphragm 16 is a field diaphragm and it is disposed between reduction means 14 and focusing means 15.

Optical system 12 also comprises operating wheels 37, 38, 39 that adjust the reduction means 14, focusing means 15 and additional diaphragm 16. More specifically, operating wheels 37 and 39 enable the focusing means 15 and reduction means 14 respectively to be displaced along the optical axis 42 while operating wheels 38 enable the opening of additional diaphragm 16 to be adjusted.

Of course, other optical systems enabling optical reduction may be used. Therefore, optical system 12 may simply comprise a negative lens that is displaced along optical axis 42. In another embodiment, one may also consider using the macro-zoom system described in document U.S. Pat. No. 3,851,952 as the optical system. One may also use camera objectives or photo apparatus objectives that perform an optical magnification or optical reduction.

In all cases, optical system 12 presents an object focal plane in which the object to be magnified or reduced is found, and an image focal plane in which the image of the object to be magnified or reduced, after reduction or magnification, is found.

To convert the optical microscope 19 into a projection device, elements from the conversion kit are added to the optical microscope.

Thus the collimated photoactivating light source 6 and the mask holder are added to optical microscope 19 such that the light rays emitted by the photoactivating light source and those emitted by the visualizing light source may follow the same optical path when they traverse the part of the projection device situated between the mask holder and the sample.

The mask holder is placed between the photoactivating light source 6 and the primary diaphragm 18. In addition, the mask holder is placed at a distance from the primary diaphragm 18 so as to leave between the mask holder and the primary diaphragm 18 sufficient space to place optical system 12 between these two elements. This free space between the primary diaphragm 18 and the mask holder may ideally measure 275 mm so as to be able to accommodate commercial optical systems.

Optical system 12 is thus then disposed between the mask holder and the primary diaphragm 18.

Optical system 12 is disposed such that the mask holder is placed in the object focal plane 43 of optical system 12 and that the primary diaphragm 18 is placed in the image focal plane 44 of optical system 12.

Filter 8 is placed before the collimated broad-spectrum visualizing light source 7 of optical microscope 19.

Selection means 30 are disposed at the intersection between the light rays from the photoactivating light source 6 and those from the visualizing light source 7 such that the selection means 30 may be placed in two positions:
In the first position, the selection means 30 direct the light beams emitted by the photoactivating light source 6 onto sample 21 by particularly passing by mask 11 and optical system 12;
In the second position, the selection means 30 direct the light beams emitted by the visualizing light source 7 onto sample 21 by particularly passing by mask 11 and optical system 12.

In the present case, in the absence of selection means, the photoactivating light source 6 emits light rays parallel to the optical axis of optical system 12 and the rays emitted by the photoactivating light source 6 illuminate the sample by passing by the mask and the optical system 12.

In addition, in the absence of selection means, the visualizing light source 7 emits light rays perpendicular to the optical axis of optical system 12, by means of the folding mirror 9, such that the light rays emitted by the visualizing light source do not illuminate the sample and do not traverse the optical system 12 or the mask.

Selection means 30 are constituted of a mirror 10 that may pivot around an axis of rotation between:
a position in which the mirror is parallel to the optical axis of the optical system 12 such that only the light rays of the photoactivating source illuminate the sample;
a position in which the mirror is tilted 45° with relation to the optical axis so as to obstruct the light rays from the photoactivating light source while directing the light rays from the visualizing light source through the mask 11 and optical system 12 such that they illuminate the sample 21.

A projection device is thus obtained from a traditional optical microscope. The projection device thus obtained is represented in FIG. 1. The projection device thus obtained is inexpensive.

In the projection device from FIG. 1, the light rays from the visualizing light source 7 and the photoactivating light source 6 take the same optical path when they traverse the mask holder, optical system 12, primary diaphragm 18 and objective 2 to arrive at sample 21.

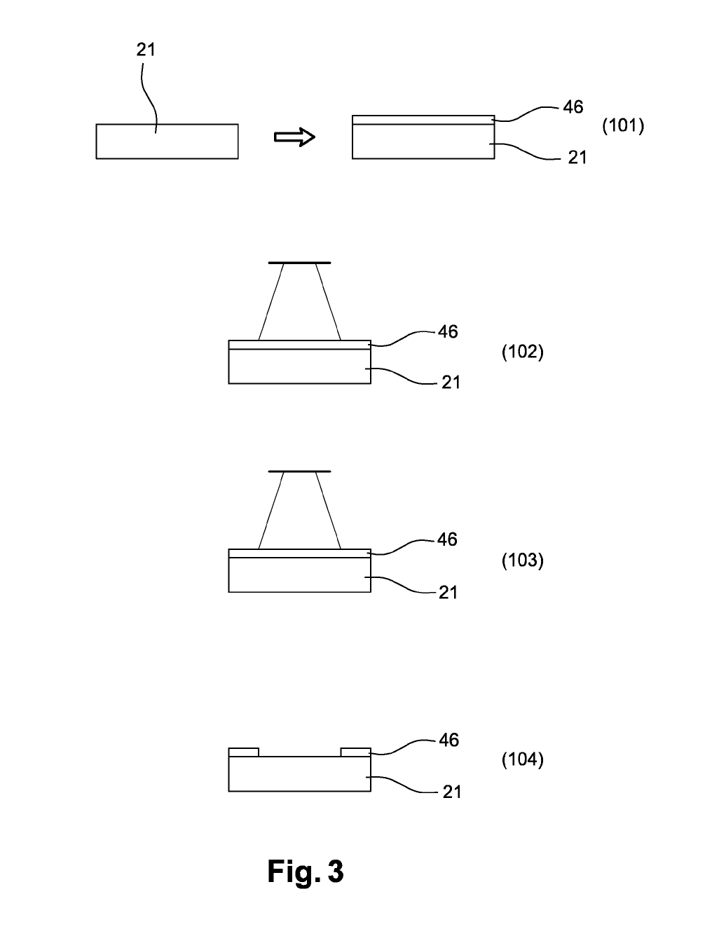

A photolithography method implemented with this projection device will now be described with reference to FIG. 3.

In a first step 101, the surface of sample 21 is covered by a photosensitive photoresist 46. This photosensitive photoresist constitutes the photosensitive zone of sample 21. Methods enabling the surface of the sample to be covered with photosensitive photoresist are well known from the prior art. For example, one may clean the surface of the sample such that the surface of the sample is as smooth as possible. The photosensitive photoresist is then spread onto the surface of the sample, for example by using a spin coating technique. The photosensitive photoresist used may for example be a photoresist that is sensitive to UV radiation; i.e., to radiation presenting a wavelength of less than 400 nm. The photosensitive photoresist may then be heated to a high temperature to be homogenized.

In a second step 102, the size of the projected pattern that one wishes to project onto the surface of the sample will be adjusted.

To do this, the sample is first placed on the sample holder 1. Possibly, the position of the sample holder may be adjusted such that the surface of the photosensitive zone is in the image focal plane of objective 2.

A mask 11 is then placed in the mask holder. This mask 11 may be constituted of a transparent sheet onto which a base pattern has been printed. The base pattern may have been printed by using a conventional printer, of the ink jet printer or laser printer type, which enables an inexpensive mask to be obtained.

Selection means 30 are then positioned such that the visualizing light source 7 projects a base pattern in filtered white light onto the sample, which enables the pattern projected onto the surface of the sample to be adjusted without modifying the photosensitive zone.

Optical system 12 enables the size of the pattern projected onto the surface of the sample to be controlled. More specifically, the optical system enables the homothety ratio between the size of the pattern projected onto the surface of the sample and the size of the base pattern on the mask to be chosen.

In fact, the base pattern image is first formed in the plane of the primary diaphragm 18 by the optical system 12. The base pattern image in the plane of the primary diaphragm is called the intermediate pattern. Optical system 12 enables the size of the intermediate pattern to be chosen. To do this, the operating wheel 39 of optical system 12 may for example be turned so as to displace the reduction means 14 along the optical axis. One may thus choose the homothety ratio between the size of the base pattern and the size of the intermediate pattern.

Focusing means 15 then compensate for the effects of the reduction means. In fact, focusing means 15 conserve the sharp image of the base pattern in the plane of the primary diaphragm 18. To do this, operating wheel 37 is turned so as to position the image of the base pattern in the plane of the primary diaphragm 18.

An image of the intermediate pattern is then formed on the surface of the sample by the objective 2 since the primary diaphragm 18 is the optical conjugate of the plane in which the surface of the sample is found. The image of the intermediate pattern on the surface of the sample is called the projected pattern.

Objective 2 may also carry out a fixed homothety between the size of the intermediate pattern and the size of the projected pattern. Thus, objective 2 may divide the size of the projected pattern with relation to the intermediate pattern by a constant k factor.

The combination between optical system 12 that carries out a variable reduction between the size of the intermediate pattern and the size of the base pattern and objective 2 that carries out a fixed reduction between the size of the intermediate pattern and the size of the projected pattern enables variable-sized, very significant reductions between the size of the base pattern and the size of the projected pattern to be obtained. The image of a centimetric pattern of mask 11 placed on the mask holder, in the object focal plane 43 of optical system 12, may thus be reduced to micron size in the image focal plane 25 of objective 2. Therefore, low-cost masks made from transparent printed sheets may be used, since even if these masks present defects, these defects may be reduced to a size of less than the diffraction limit.

In addition, focusing means enable having a pattern projected on the surface of the sample that is always sharp and focused regardless of the homothety ratio between the projected pattern and the base pattern.

Optical system 12 also comprises an additional diaphragm 16 that enables the brightness and contrast of the pattern projected onto the surface of the sample to be adjusted.

One may also consider having a mask 11 that rotates with relation to the optical axis 42 of the optical system 12, such that the orientation of the mask with relation to the surface of the sample may be chosen.

Thus, during this second step 102, the size of the projected pattern, and possibly its orientation, are adjusted by using light from the visualizing light source 7, such that the photosensitive zone is not damaged during this step.

The method then comprises a third step 103 during which the projected pattern is formed on the sample with the radiation emitted by the collimated photoactivating light source 6.

To do this, selection means 30 are positioned such that the visualizing light source 7 no longer illuminates the sample but it is the photoactivating light source 6 that projects the pattern projected onto the photosensitive zone of the sample.

The duration during which the photoactivating light source projects the pattern projected onto the surface of the sample depends on the desired exposure time.

Once the photosensitive photoresist has been exposed, the photolithography method comprises a step 104 during which the exposed parts of the photoresist are eliminated when the photoresist is positive, or else the non-exposed parts of the photoresist are eliminated when the photoresist is negative.

Elimination of the exposed parts may for example be carried out by immersing the sample in an NaOH or KOH solution diluted in water.

Naturally, the invention is not limited to the embodiments described with reference to the figures. Thus, the projection device may also be used for applications other than photolithography: In particular, it may be used to locally activate chemical or biological species that are photosensitive.

1. A device for projecting a pattern onto the surface of a sample (21) that comprises at least one photosensitive zone, the projection device being characterized in that it comprises:
a mask (11) defining a base pattern,
a photoactivating light source (6) able to illuminate the sample (21) through the mask (11) with radiation to which the photosensitive zone is sensitive so as to define a projected pattern on the sample (21);
a visualizing light source (7) able to emit visible radiation that illuminates the sample through the mask;
an optical system (12) disposed between the mask (11) and the sample (21), the optical system (12) being able to carry out controlled homothety between the size of the base pattern and the size of the projected pattern such that the size of the projected pattern is continuously varied without the size of the base pattern varying;
selection means (30) able to select either said photoactivating source or said visualizing source such that one passes from a visualization mode to a writing mode and vice-versa where:
said visualization mode is a mode for adjusting the size of the projected pattern where the sample is illuminated through the mask thanks to the visualizing light source and;
said writing mode is a mode where the sample is illuminated through the mask thanks to the photoactivation source such that the projected pattern defines a photosensitized zone.

2. The device according to claim 1, wherein the device further comprises
an objective (2) presenting an image focal plane (25) and an object focal plane (24), the sample (21) being disposed in the image focal plane (25) of the objective (2);
a primary diaphragm (18) disposed in the object focal plane (24) of the objective (2), the photoactivating light source (6) being able to illuminate the plane (26) in which the primary diaphragm (18) is found so as to define an intermediate pattern in the plane (26) of the primary diaphragm (18),
wherein the optical system (12) presenting an object focal plane (43) in which the mask (11) is situated and an image focal plane (44) in which the primary diaphragm (18) is situated, the optical system (12) being able to carry out controlled homothety between the size of the base pattern and the size of the intermediate pattern.

3. The projection device according to claim 2, wherein the optical system (12) further comprises reduction means (14) able to control the size of the intermediate pattern.

4. The device according to claim 3, wherein the optical system presents an optical axis (42) that is merged with the optical axis defined by the light source and the mask, and the reduction means (14) comprise an afocal system comprising two negative lenses (33, 34) separated by a positive lens (35), the negative lenses (33, 34) and the positive lens (35) may be displaced along the optical axis (42) of the optical system so as to control the size of the intermediate pattern.

5. The device according to claim 3, wherein the optical system (12) presents an optical axis (42) and the reduction means (14) comprise a negative lens able to be displaced along the optical axis (42) of the optical system so as to control the size of the intermediate pattern.

6. The device according to claim 2, wherein the optical system (12) also comprises focusing means (15) able to adjust the definition of the intermediate pattern.

7. The device according to claim 2, wherein the optical system (12) also comprises an additional diaphragm (16) able to adjust the brightness and contrast of the intermediate pattern that is formed in the plane of the primary diaphragm.

8. The device according to claim 1, wherein the device also comprises a filter (8) able to filter and absorb the radiation emitted by the visualizing light source (7) and to which the photosensitive zone is sensitive.

9. The device according to claim 1, wherein the device also comprises a system of controlled displacement enabling the sample to be laterally and axially displaced as well as a switching system enabling the controlled switching on and switching off of the photoactivating light source.

10. A photolithography method using a projection device according to claim 1, wherein the method comprises the following steps:
(a) a step (102) of adjusting the size of the pattern projected onto the surface of the sample by using radiation (22) emitted by the visualizing light source (7);
(b) a step (103) of projecting the pattern projected onto the sample with the radiation emitted by the photoactivating light source (6);
(c) a step (104) of eliminating the parts of the photosensitive zone that have been exposed to radiation or else a step of eliminating the parts of the photosensitive zone that were not exposed to radiation.

11. The photolithography method according to claim 10, wherein the size of the projected pattern is reduced with relation to the size of the base pattern.

12. A method for photoactivating chemical or biological species using a projection device according to claim 1, wherein the method comprises the following steps:
(a) a step (102) of adjusting the size of the pattern projected onto the surface of the sample by using radiation (22) emitted by the visualizing light source (7);
(b) a step (103) of projecting the pattern projected onto the sample with the radiation emitted by the photoactivating light source to locally activate chemical or biological species that are photosensitive.

13. The method according to claim 10, wherein the mask is formed by a transparent sheet on which the base pattern is printed.

14. A method to convert an optical microscope into a device for projecting a pattern onto the surface of a sample comprising at least one photosensitive zone, the optical microscope comprising:
an objective (2) defining an object focal plane (24) and an image focal plane (25);
a primary diaphragm (18) disposed in the object focal plane (24) of the objective (2), the primary diaphragm (18) extending in a plane (26);
a visualizing light source (7) able to emit visible radiation;
the sample (21) being disposed in the image focal plane (25) of the objective (2);
the conversion method comprising, in any order, the following steps:
a photoactivating light source (6) emitting radiation to which the photosensitive zone is sensitive so as to define a projected pattern on the sample (21) is added to the optical microscope;
a mask (11) disposed between the photoactivating light source (6) and the sample (21) is added to the optical microscope, the mask (11) defining a base pattern;
an optical system (12) disposed between the mask (11) and the sample (21), the optical system (12) being able to carry out controlled homothety between the size of the base pattern and the size of the projected pattern is added to the optical microscope;
selection means (30) able to select either said photoactivating source or said visualizing source such that one passes from a visualizing mode to a writing mode and vice-versa are added to the optical microscope, where:
said visualization mode is a mode for adjusting the size of the projected pattern where the sample is illuminated through the mask thanks to the visualizing light source and;
said writing mode is a mode where the sample is illuminated through the mask thanks to the photoactivation source such that the projected pattern defines a photosensitized zone.

15. The method according to claim 14, wherein the image focal plane (44) of the optical system (12) is placed in the plane (26) of the primary diaphragm (18).

16. The method according to claim 14, wherein the mask (11) is placed in the object focal plane (43) of the optical system (12).

17. The method according to claim 16, wherein the method also comprises a step of adding a filter (8) able to filter and absorb the radiation emitted by the visualizing light source (7) and to which the photosensitive zone is sensitive.

18. The method according to claim 14, in which the optical system (12) comprises:
reduction means (14) able to control the size of the image of an object;
focusing means (15) able to adjust the definition of the image of the object;
an additional diaphragm (16) able to adjust the brightness and contrast of the image of the object.
